(19) United States
(12) Patent Application Publication
(10) Pub. No.: US 2023/0034578 A1
(43) Pub. Date: Feb. 2, 2023

(54) 3D DRAM WITH LAMINAR CELLS

(71) Applicant: John Bennett, Sammamish, WA (US)

(72) Inventor: John Bennett, Sammamish, WA (US)

(21) Appl. No.: 17/389,235

(22) Filed: Jul. 29, 2021

(51) Int. Cl. H01L 27/108; G11C 5/06; H01L 23/522; H01L 23/528

(52) U.S. Cl. CPC H01L 27/10897; G11C 5/063; H01L 27/10805; H01L 23/5226; H01L 23/5283; H01L 23/5286

(57) ABSTRACT

Systems and methods are described herein for dynamic random access memory (DRAM) devices. In one aspect, a plurality of DRAM cells forms a stacked structure. Individual DRAM cells may include a substantially planar capacitive element formed of two substantially planar electrodes separated by an insulating layer. Individual DRAM cells may also include a transistor in communication with and substantially planar to the capacitive element, and a word line, which activates the access gate of the transistor when a voltage is applied to the access gate, formed proximate to and substantially parallel with the capacitive element. Individual DRAM cells may share at least one data line, oriented in a vertical direction relative to the stacked structure, that is in communication with capacitive elements through the access gate of individual DRAM cells and is operable to store and access charge stored in individual capacitive elements of individual DRAM cells.

### BACKGROUND

Modern Dynamic Random Access Memory (DRAM) and digital Logic circuits are both constructed from semiconductor devices but use different and largely incompatible processes. The high processing temperature and low leakage materials used for DRAM are not mixable with the tiny, high speed and more leaky logic devices. Logic processes continue a path of relentless improvement currently around 15% per year in either speed or reduced power, while DRAM process has a much slower rate of improvement. This means that not only are the processes incompatible, but also the price and performance are drifting out of balance, such that there is a need for new memory devices that can close the gap.

The currently prevalent process for DRAM uses capacitor cells constructed as slim, tall cylinders above the logic for selection and data input and output (I/O). This DRAM process is running into limits due to the need for cylinders large enough for charges to be detected by sense amplifiers after dilution of the charge over the relatively long data-line conductors which connect charge stored in the capacitors to the sense amplifiers which decide if the charge matches a zero or a one. Scaling to smaller device dimensions does not reduce the resistance-capacitance load represented by the data-line, and the cylinder capacitors are nearly at the end of size reduction if they are to retain the charge needed for a 1-transistor, 1-capacitor (1T1C) Dennard memory cell composed in an array with long data-lines which diminish the signal before it reaches sense amplifiers. The fabrication of these cylindrical capacitors is demanding and slow, accounting for much of the cost and production capacity limitation of current DRAM chips.

### BRIEF DESCRIPTION OF THE DRAWINGS

Various techniques will be described with reference to the drawings, in which:

FIGS. 1-15 illustrate example stages of a process to form a layer of a memory cell, in accordance with at least one embodiment;

FIG. 16 illustrates an example two layer memory cell, such as may be produced via the one or more stages of the process illustrated in FIGS. 3-15, in accordance with at least one embodiment;

FIG. 17 illustrates an example multi-layer memory cell, such as may be produced via the one or more stages of the process illustrated in FIGS. 3-15, in accordance with at least one embodiment;

FIG. 18 illustrates the example multi-layer memory cell of FIG. 17 with a vertical data-line via, in accordance with at least one embodiment;

FIG. 19 illustrates a cut-away view of the via illustrated in FIG. 18, in accordance with at least one embodiment;

FIG. 20 illustrates the memory cell of FIG. 18 with word lines that contact the vertical via, in accordance with at least one embodiment;

FIG. 21 illustrates an example memory cell that includes multiple memory cells, such as memory cells illustrated in FIGS. 18 and 20, placed adjacent to one another having extended word-lines, in accordance with at least one embodiment;

FIG. 22 illustrates an example configuration of vertical vias, such as extending from the memory cell of FIG. 21, etched down to contact the individual word-lines at their landing-lines, in accordance with at least one embodiment;

FIG. 23 illustrates an example memory cell, such as the memory cell of FIG. 21 or 22, with sense amplifiers added at the top and data-line contacts extending down from the CMOS layer to the underlying data-line vias, in accordance with at least one embodiment;

FIG. 24 illustrates an example correspondence between the core elements of a single bit memory cell, as described in any of the FIGS. above, and a logical circuit diagram equivalent, in accordance with at least one embodiment;

FIGS. 25-32 illustrate another example of stages of a process to form an alternative memory cell layer, in accordance with at least one embodiment;

FIG. 33 illustrates an example multi-layer memory cell, such as may be produced via the one or more stages of the process illustrated in FIGS. 25-32, in accordance with at least one embodiment;

FIG. 34 illustrates an example set of memory cell layers that have data-line vias through the middle of the bridges, in accordance with at least one embodiment;

FIG. 35 illustrates how a sense amplifier may be constructed in a complementary metal-oxide-semiconductor (CMOS) layer above a multi-layered memory cell, such as illustrated in FIG. 33 or 34, in accordance with at least one embodiment; and

FIG. 36 illustrates an example correspondence between the core elements of a single bit memory cell, as described in any of the FIGS. 25-35 above, and a logical circuit diagram equivalent.

### DETAILED DESCRIPTION

Systems and methods are descried herein relating to Dynamic Random Access Memory (DRAM) devices. Systems and methods are described herein for dynamic random access memory devices (DRAM). In one aspect, various DRAM cells, formed of layered materials and substantially planar, may be formed in a in vertical orientation, such that the data-lines run perpendicular to the surface of the substrate and any number of layers may be stacked on top of one another. The various stacks of cells may then be arranged in various ways in an area to form a high density of cells, which may be multiples more dense than is currently possible with state of the art DRAM chips. The devices may be conventional capacitor cells with the usual need for refresh, and the other usual features of activation, sensing, write-back, and selection which are common to Dennard-cell 1T1C DRAM. The cells may also use ferroelectric capacitor dielectric thus resulting in devices which hold charge indefinitely without refresh, but in most other respects operate similarly to the conventional cells, while possibly having limitations on the total number of use cycles they can endure. Two example methods of construction with differently proportioned elements and alternative manufacturing steps are detailed.

In some aspect, the new approach described herein abandons cylinder-type capacitors, turns the memory cells on their side with the inevitable smaller capacitance, and frees up some new ways to optimize memory in a 3-dimensional stack of cells. In some aspects, the capacitors become broader structures which can be created with thin, flat layers which may be stacked multiple cells high. The data-lines (also known as bit-lines) become vertical to intersect those multiple thin layers while remaining approximately 20 times shorter than in the 2D surface form. While the thin planar capacitors store less charge than the cylinders, the shorter data-lines function properly with that smaller charge. These flat capacitors are inexpensive due to the simple manufacturing process needed to produce them, and many cell layers can be stacked. This layering technique may be utilized to result in far superior bits per unit area than the current approach, and the simple process to form each layer results in a low cost per bit. The short data-line enables fast operations. The formation uses uniform planes of insulator which are advantageous for advanced dielectrics such as ferroelectrics. The structure also screens cells from their neighbors which reduces disturbance effects. The smaller cell capacitance and short data-lines will allow read and write power to be minimized.

The novel insights that led to the design of the descried memory cell and its variations include one or more of the following 1) to accept the much smaller capacitance but then make it practical with short data-lines in a vertical approach, 2) to accept that the layers of cells will require shaping but to simplify the cell such that the construction costs will be cheap enough per bit to make the whole device worth building even though cell density of a single layer of such primitive devices may not be competitive with the current state of the art for memory cells, and 3) to accept that the processing may require unusual materials or application of uncommon annealing processes.

The heart of each memory cell or device is a planar semiconductor active core, which is formed of material from a uniformly deposited layer, which is then patterned. In some cases, the layers may be annealed to optimize material qualities of semiconductor films ranging from silicon to semiconducting oxides such as TiO2 (titanium dioxide), WO3 (tungsten trioxide), IWO (indium oxide with tungsten doping) or IGZO (indium gallium zinc oxide formulations), or other semiconductors compatible with deposition as thin as a few nanometers, that retain good electrical performance.

The device stacks may have large layer counts leading to high combined capacities, potentially thousands of bits per square micron. This high capacity can amortize the cost of a top or bottom layer of CMOS supporting circuits fabricated in high quality single crystal silicon. When the CMOS layer is bonded on top, an approach used for SOI (silicon on insulator) devices, after the memory layers are formed, allows for annealing processes which may be too hot to be compatible with logic elements. Thus, when the logic layer is added after the annealing there is extra freedom to choose the materials used in the memory cells.

There can also be cost and complexity advantages in having the CMOS support circuits built first and then building the DRAM layers above that logic and analog circuitry. Some materials available, which can be processed at lower temperatures, can form just the same kind of laminar memory structures. In these examples, the materials chosen may be more limited, but this may be outweighed by the advantage of working with a cheaper circuit under memory fabrication. This may provide a lower cost approach avoiding the SOI bonding step, attractive for memory stacks that do not need the ultimate capacity.

The memory device described herein is different from other 3D memory proposals in adhering to the proven single transistor single capacitor (1T-1C) “Dennard cell” principles with speeds and operation which are compatible with existing industry practice. One innovation of the described memory device lies in seeing how that functionality may be maintained while finding a structure that is compatible with extension to multiple layers in the vertical direction, with simple and inexpensive fabrication. Unlike the 3D fabrication of NAND in which potentially hundreds of featureless layers are the key to overall cost reduction, the described DRAM techniques accept that some of the layers will require masking steps to obtain shapes for device elements through etching or selective deposition or implantation, while delivering functionality compatible with prior DRAM devices.

The systems and techniques described herein may enable the production of memory chips or devices which have the functions and capabilities of current DRAM devices but may be manufactured with higher capacity per unit area, at low cost and with good performance. In some aspects, each cell is a 1-transistor 1-capacitor (1T1C) single bit memory based on the principles of the original 1T1C cell which is well known in the industry. The described memory cell may use either an ordinary dielectric, a ferroelectric, or an anti-ferroelectric dielectric in the capacitor. Semiconductor substrates may be constructed where multiple layers of DRAM cells are simply and inexpensively fabricated such that, with many layers, an exceptionally high cell density is obtained which may be coupled with access circuits either below or above the DRAM cells.

Cells with ordinary dielectric will have unlimited endurance and high speed but require refresh as the capacitor charge will leak through the access transistor. Refresh cycles may be reduced or eliminated by operating at lower temperatures which reduce leakage and increase the sub-threshold slope, improving the on/off ratio of the access transistor. Cooler operation may widen the choices for suitable semiconductor thin films within the decks. Even at room temperature, thin film semiconductors such as titanium dioxide with a 100,000,000 to 1 on/off ratio are known and would be suitable to support conventional refresh intervals of 64 milliseconds while supporting access times of a few nanoseconds.

Cells with ferroelectric dielectric will retain charge indefinitely when operated with sufficient positive and negative voltages to reach the necessary hysteresis in the dielectric material. In addition to the persistence of charge they also are tolerant of access channel transistors with less perfect on/off ratios, which provide more choices for semiconductor selection. For example, polysilicon channels with an on/off ratio around 1,000,000 to 1 would be suitable. There may be some limits to the cycles of operation, requiring wear leveling methods to be added to the access path. It will be possible to use the highest performance orthorhombic hafnium-zirconium oxide or other recently discovered ferroelectrics especially if CMOS-after construction is chosen, as will be discussed in greater detail below, since memory stack materials may be used which require annealing without concern for temperature limits in the CMOS devices.

Cells with antiferroelectric dielectric have reported charge retentions of many seconds even at elevated temperature and tolerate moderate access channel performance. They do, however, require different sense amplifiers methods which may require more complex sense amplifiers to be multiplexed for sharing by a broader set of data lines.

The high capacity of the multiple DRAM levels supports the cost of the additional steps needed to integrate CMOS under or over the memory array, since only one final CMOS layer has its cost shared by dozens of memory layers. The resulting devices will enable high capacity, high performance, general purpose memory to be built at low cost per gigabyte and low power of operation compared to current DRAM.

The use of CMOS above has the utility of integrating the densest general-purpose memory— DRAM— alongside the best of logic devices that results in an improvement in performance and reduction in the energy needed for data access. The CMOS layers enable high quality analog and digital circuits to be incorporated with direct access to adjacent memory cells.

Other circuits built at the CMOS level may include the overall interface for the memory chip, error correction, sparing, and other supervisory overhead for the chip. Various forms of interface and control such as Open Memory Interface (OMI), Low Power Double Data Rate (LPDDR), Double Data Rate (DDR), Graphics Double Data Rate (GDDR), or High Bandwidth Memory (HBM), will be feasible. In some aspects, other interfaces and/or controls may be implemented that make better use of the good quality CMOS process for the control and interface logic which offers performance not matched with processes optimized for DRAM elements.

It is also possible to add Processing In Memory (PIM) functionality to the CMOS layer, or to bond one or more additional semiconductor layers on top to implement CMOS functionality which does not compete with the sense amplifiers in the first CMOS layer. This can be facilitated by substrate materials with greater heat conductivity, and in environments which can provide cooler package temperatures.

Non-silicon substrates such as graphite could be used to support the construction of the memory stacks since the memory stacks are not electrically connected to the substrate. Graphite may be toughened by alloying, for example with tungsten or silicon, and offers an order of magnitude better thermal conductivity than silicon. This will support the removal of heat if additional layers of processing logic are bonded or packaged together with the memory stack. Substrates with slightly different thermal expansion coefficients may be accommodated by etching trenches around the memory regions to allow some expansion and contraction.

If silicon is used as the base wafer, it does not need to be highly pure and crystalline, since the memory layers are not electrically connected to the base. It could, for example, be inexpensive epitaxial polysilicon on a carrier plate, or melt-cast polysilicon wafers. Other low-cost silicon sources may be used.

Elements in the memory layers may benefit from annealing and other high temperature processes that improve their semiconductor or dielectric quality. This is especially enabled by a CMOS-last order of construction where the memory stacks may be thermally processed prior to the formation of the CMOS above it, and all the materials in the memory stacks may be selected to be tolerant of the deposition, crystallization, and annealing temperature profiles encountered during the construction of the stacks.

Nevertheless, there are also materials known which can be formed and annealed at temperatures under 400C which are generally compatible with implementations that utilize CMOS-first under the memory, that form devices which would be present during the memory array construction. To allow connections down to the CMOS, below the base conductor level of the memory cells would need to be masked to open a path for vias to be etched downward to start in the CMOS. Both CMOS-first and CMOS-last are compatible with the described 3D DRAM array construction with appropriate choice of materials and matching construction of the vias.

The memory stack and CMOS layers may use different processes but may be integrated in design for a precise match in the position of connecting features. Precise combination and alignment is already used in sequential stacking Silicon on Insulator (SOI) processes which bonds a thin epitaxial blank SOI layer on top and then uses alignment marks in the base, which are visible through such thin epitaxial oxide and silicon, so that the next levels of lithography are aligned within nanometers of the underlying memory stack. The use of these processes allows true 3D integration at the limits of device geometry.

The memory stack does not require power and ground distribution as its devices are passively powered by sense amplifiers and other signal drivers such as the word-line drivers. Areas of the memory substrate which are not used for memory stacks, for example because the CMOS area above must be used for non-memory functions, may be patterned with structures, including capacitors or conductors or inductors, which support power and ground distribution for the CMOS functions.

In some aspects, the multiple, wide ground planes may greatly reduce disturbance effects, and the short data-lines should deliver low latency with small charge transfers. This will support reliable and high-performance operation.

Both volatile and persistent forms are possible, depending on the kind of dielectric in use. The planar construction allows dielectrics of ideal uniformity in thickness and composition to be deposited by a variety of technologies including wet chemical, plasma, sputtering, molecular beam, and vapor deposition schemes, possibly modified by dopant implantation and by annealing. The materials used will each have their ideal deposition methods. The planar construction of the capacitors including fill materials to minimize level changes at the semiconductor edges will minimize material stress from changes in field intensity that occur around folds, generally allowing best results even with complex dielectrics.

In some realizations, the deck may be constructed with two memory facing each other around a central, shared conductor. The upper cell is a mirror image of the lower cell. In that case the use of three ground planes and two semiconductor central electrodes within a deck allows two semiconductor planes with dual-sided capacitors which doubles the capacitance per unit area.

Capacitance per cell will depend upon choice of dielectric and thickness, but values around 1 femtofarad per cell are estimated for conventional capacitor dielectrics with areal density of 100 cells per square micron per deck. This is approximately 10-fold smaller than was found in the cylindrical capacitors for devices in the DDR4 generation. In some aspects, this may be an effective match to data-lines, which may be 20× shorter than for the horizontal data-lines of those same DDR4 devices.

The word-line access vias may utilize unique lithography patterns to give a different access to the word-line for each distinct deck. For example, 24 deck stacks might require 24 different lithography masks specialized just for those word-line layers. The standard approach to providing vias reaching individual layers is the stair-step formation as is found in 3D-NAND chips. In order to avoid too many stair-steps, which takes time to process and space on the chip, there can be a small number, such as 4, of different masks which provide word-line terminations in 4 different places. This allows one stair-step to be divided by 4 (or whatever number is optimum) because there are separate word lines reachable in each stair-step. The small set of different masks would be repeated in groups, so for example 32 decks might be constructed with 4 different word-line masks repeated in a cycle, then 8 stair-steps are etched to allow the word-line vias to reach all 32 word-lines distinctly.

The other way of address the problem of word line implementation is to use mask less lithography, such as electron beam lithography, for just the distinctive details of the layers which need variations in detail. It is not necessary for the entire layer to be drawn with electrons, which would be impractical with current machines. The variations in word lines occupy less than 0.1% of the pattern, so a combination of conventional lithography with a single mask can expose the unchanging parts of the conductor layers which include word-lines, then electron lithography can be applied to finish exposing the resist for just the tiny area needing custom details to extend the word line to a distinct landing. That may be feasible at production rates with currently available multi-beam electron lithography.

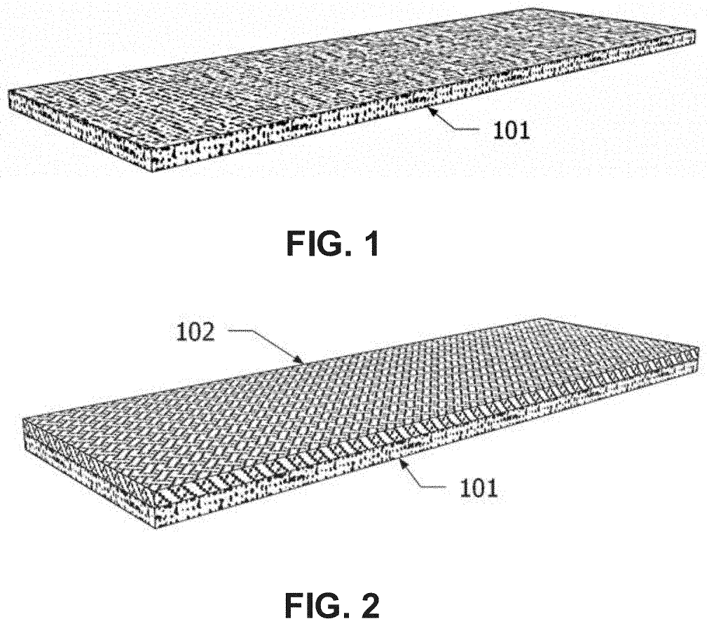

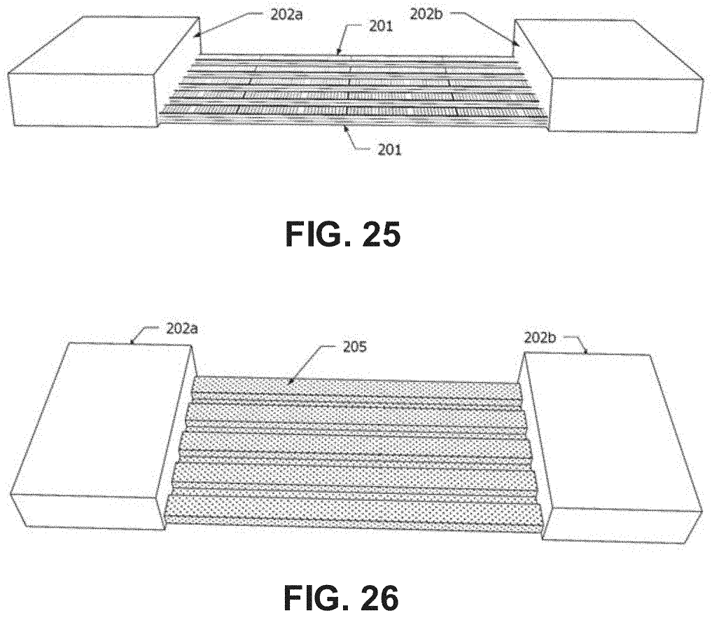

Different stages of an example process for creating a layer of a memory cell are described in reference to FIGS. 1-15 below. It should be appreciated that the various stages illustrated in the example process are given by way of example, and that various steps or stages may be combined, or omitted, and other steps may be added, as will be appreciated by those having ordinary skill in the art. As used herein, a deck may refer to a number of layers formed together to create one memory cell, such that can hold 1 bit of information. A stack may refer to any number of decks stacked on top of each other. As described below, FIGS. 1-24 refer to a first implementation of a DRAM memory device, whereas FIGS. 25-36 refer to a second implementation of DRAM memory device. While these devices are illustrated and described as distinct, it should be appreciated that one or more steps or techniques utilized for one memory device may similarly be used for the other memory device.

The example process may begin with construction of a deck which is a set of layers forming DRAM cells with a central core of semiconductor sandwiched below and above by dielectrics and conductors. The different parts of the semiconductor interact with these other layers to create capacitance, an access channel, and a contact to the data-line. This set of layers for a cell, which will be termed a deck, may then be joined by more layers fabricated one over another to form a stack of multiple decks. In some examples, the active circuitry for sense amplifiers and other system functions may be formed or placed above the multiple decks. In other examples, some or all of the active circuitry may be placed below the first layer of the deck, split between above and below the deck, or placed within the decks.

FIG. 1 illustrates an example first step in fabricating a deck with a single memory cell layer. This step forms a conductive ground plane 101, which acts as a bottom plane and isolation of the lower cell capacitors (e.g., when this memory cell is stacked on top of other memory cell layers). These planes may remain at a constant reference voltage which functions as a ground plane for the capacitors in the first layer of devices. In some cases, this bottom plane may be substrate if it is conductive.

FIG. 2 illustrates that an insulating etch-stop material 102 is deposited over the base ground plane 101. This etch-stop material is an insulator which resists the etching processes used to form vertical connections, to prevent contact with the base ground plane conductor 101.

As described herein, it should be appreciated that some or all layers are deposited by successive methods of vapor, molecular beam, sputtering, liquid chemistry, electroplating, plasma, ion implantation, or other deposition methods used in the semiconductor industry, as may be suitable for fabrication of the specific materials. Etching and removal may be done by evaporation, solvents, acids, reactive plasma, chemically enhanced plasma, and other removal methods used in the semiconductor industry. The methods used for depositing or removing materials at each step may be optimized for construction of a device made of certain materials, as is known by those of ordinary skill in the art.

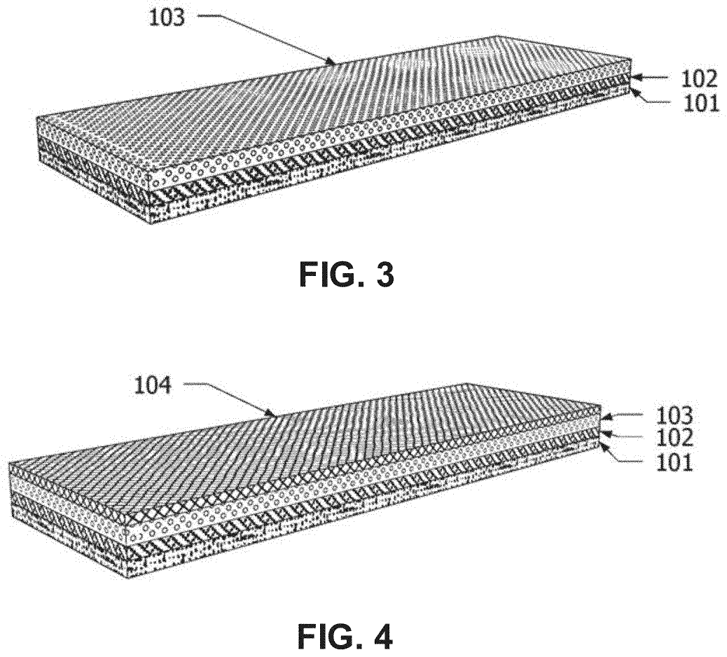

FIG. 3 illustrates that a uniform insulating plane 103 is now added on top of the etch-stop material 102. Since this layer 103 is insulating, it does not need to be patterned and may be a uniform deposit across the entire device or base layer, electrode, or ground plane 101. This dielectric in this example may be selected to have a low dielectric constant (permeability symbol usually written as “k”, hence a “low-k” material) and of enough thickness to give a low coupling from the base ground plane 101 to the signal-carrying semiconductor elements which will come above layer 103. The dielectric may be comprised of multiple layers of materials to optimize its quality and efficiency. It may also be chosen such that its top chemistry promotes the ideal form, orientation, or crystallization of the semiconductor material to be used in the next layer.

FIG. 4 illustrates that the next step is the addition of a semiconductor layer 104 as a plane, which may be a uniform plane, above the lower insulator 103. After depositing this layer 104, it may be annealed or otherwise treated to improve its material structure and electrical properties. The annealing and treatment process may in some variants be delayed until multiple memory layers are present, to amortize the time and cost of the process across all layers.

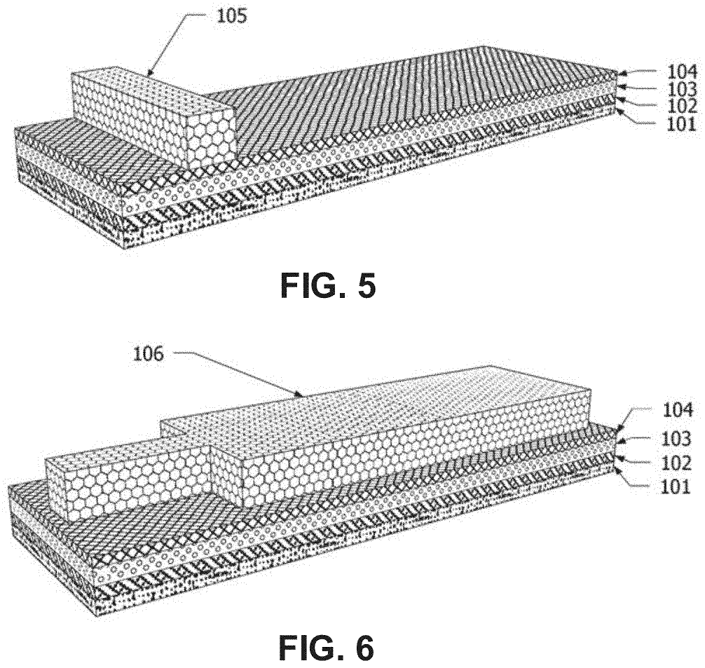

FIG. 5 illustrates the use of a mask 105 to separate the part of the semiconductor which will be the access channel underneath the mask 105, from the rest of the semiconductor which will be treated to be more conductive. The access channel needs to be capable of shutting off with low leakage. This often requires the semiconductor to be “fully depleted” (no doping atoms present) or to have a low rate of positive doping atoms (p-doped) which will trap electrons unless the gate region has a strong field applied to enable electrons to flow through the channel. The ease of conduction in the remaining area of the semiconductor will generally be achieved by adding a generous quantity of negative or n-dopant atoms which contribute free electrons. It is also possible to simply deposit a thin conductive upper layer on the semiconductor. The mask 105 shields the channel region from the dopant implantation or conductive deposition.

FIG. 6 shows the step after the doping step is complete, in which the doping mask 105 has been removed, and a cell pattern mask 106 is added. This pattern defines the shape of the semiconductor element to be retained.

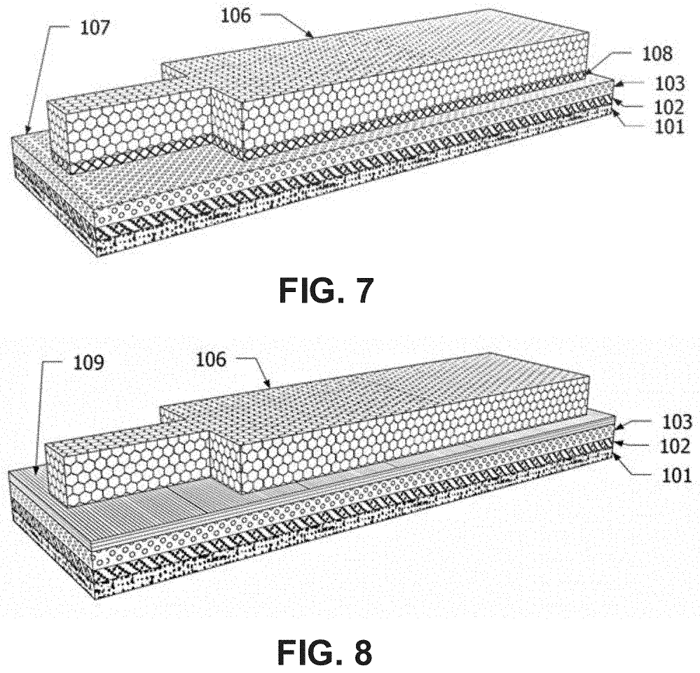

FIG. 7 shows the result of using the shape mask 106 to guide the removal of the semiconductor in regions 107 where it is not required, leaving the shaped semiconductor 108, which is the core of the bit cell. The removal process should not remove the underlying insulators 103 or 102, nor affect the base conductor 101.

In processes such as shown in FIGS. 5, 6, and 7, it is generally possible to implement the same patterns by masks of complementary design (additive vs. subtractive method) and order of formation of the semiconductor vs. the doping and the filler within that layer. For example, it is possible to lay down a uniform filler, then add a mask which leaves openings for the semiconductor, such that the filler is then removed within those openings and the semiconductor is deposited up to a thickness matching the filler, then the mask may be removed. Such variable approaches should be understood to be possible for all masking steps described herein. A preferred approach to delivering the device feature is a matter of optimization matched to the materials to be used for fillers, conductors, and semiconductors, and such optimizations would be known to those skilled in the art of semiconductor device manufacture. These FIGS illustrate one example approach.

FIG. 8 illustrates the growth of a low-k insulating filler 109 to approximately the same thickness as the semiconductor 108, guided by the same mask 106 in a self-aligning step to complement the semiconductor shape. This filler 109 may be chosen for a low dielectric constant and for suitability for etching of the vertical elements later, or which have other desirable filling properties. Additionally, it may use a chemical conversion of some of the semiconductor layer which may have been incompletely removed in region 107. For example, if the semiconductor is silicon, the exposed areas not under the mask may be oxidized into insulating silicon dioxide. The underlying layers 103, 102, 101 are not altered by the addition of the filler.

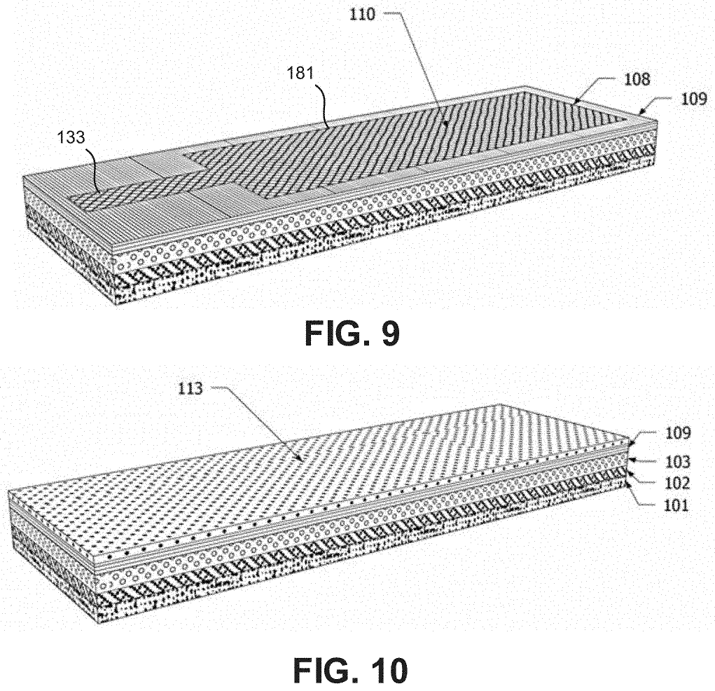

FIG. 9 illustrates the semiconductor layer 108 and matching filler 109 after the mask 106 is removed at area 110. The semiconductor 108 has broad sections 181 suitable to be the center electrode of the storage capacitor, and a narrower bridge 133 which may be used to form access channels that will control the flow of current to or from the capacitors to the end of the bridge, which is where the vertical vias of the data-lines may be connected in a later step. In some examples, the bridge may connect to another cell which is its reflection, meeting at the bridge. Each cell may have its own access channel and be separately enabled, so they can share the middle of the bridge where the data-line connection will be made. Cells above and below may connect to the same data-line. Only one cell is enabled at a time. The access channels isolate all the other cells.

FIG. 10 illustrates the addition of another dielectric plane 113, which forms an insulating layer on the top side of the central semiconductor 108. The composition of dielectric plane may be selected to have a high-k value and be as thin as is compatible with reliable operation. This layer 113 will act as a gate dielectric above the access channel part 182 of the semiconductor 108, and as a capacitor dielectric between the broad cell of semiconductor and a ground plane which will be added next. In some cases, this dielectric may be ferroelectric or antiferroelectric, in which cases an additional step may be added which, under a mask not shown, dopes or alloys the dielectric differently in the region of the access gate which may require conventional insulator functionality. The dielectric 113 may be comprised of multiple layers of materials to optimize its quality and efficiency, as well as to induce special properties of direction of crystallization or added dopants, which are techniques that may be used in ferroelectrics and antiferroelectrics. The dielectric 113 may be a uniform layer also covering the filler 109, with no masking required for formation/deposition of the dielectric 113.

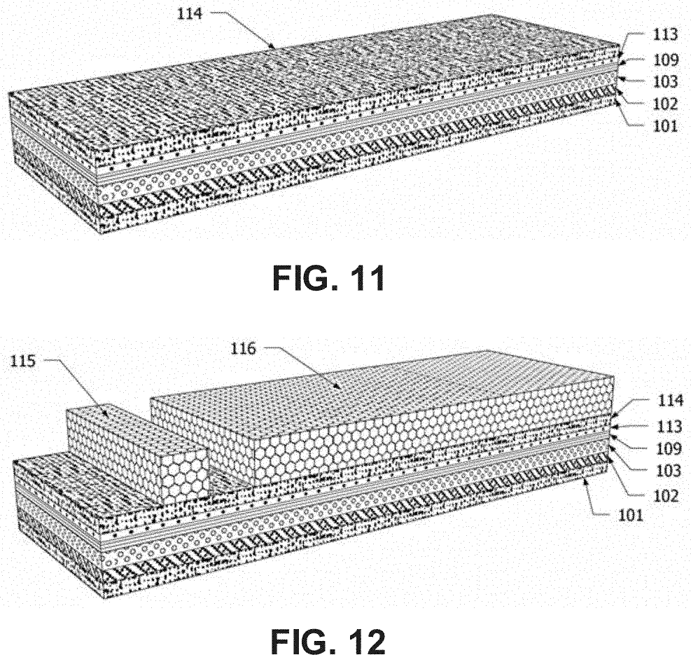

FIG. 11 illustrates the addition of another uniform layer of conductor 114, which will be used for the word-line and the top ground plane of the capacitor. The voltage on this ground plane 114 may be 0V, or half of the main supply voltage Vcc, or Vcc itself, or any other constant voltage chosen to optimize capacitor and system operation. For example, use of 0 V may be simple to arrange, while Vcc/2 may reduce average leakage and be compatible with ferroelectric capacitors which need to be able to go both positive and negative relative to the reference electrode. Use of Vcc/2 may also simplify and improve speed on the equalization phase of sense amplifier operation. The ground planes 114 in the multiple layers of the stack may be connected to the same reference voltage, for uniform operation of all cells.

FIG. 12 illustrates the addition of a word-line mask 115 and a capacitor ground plane mask 116, which will guide the formation of the word-line and capacitor ground plane. In some cases, a complementary mask set may be used and conductor 114 may be selectively added.

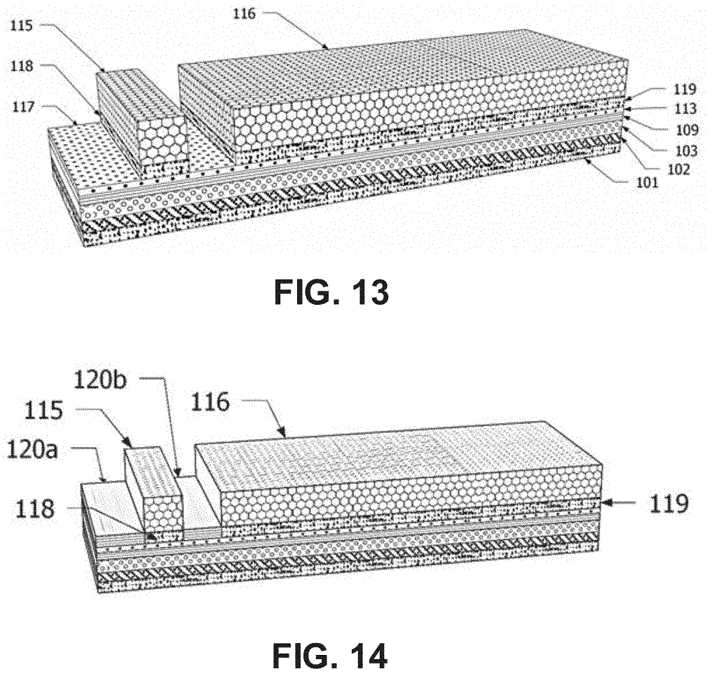

FIG. 13 illustrates the removal of the conductor 114 in areas where the conductor layer 114 is not needed, leaving in place the word-line 118 and ground plane 119.

FIG. 14 illustrates the addition of filler in regions 120a and 120b where the conductor 114 is absent, with a thickness to match the conductor 114 for a substantially level top surface of conductor and filler together. The filler may be newly deposited or may additionally be formed by chemical conversion of any remaining unwanted conductor. The filler 120a and 120b may be elected to have a low-k value and be compatible with later etching for vertical vias.

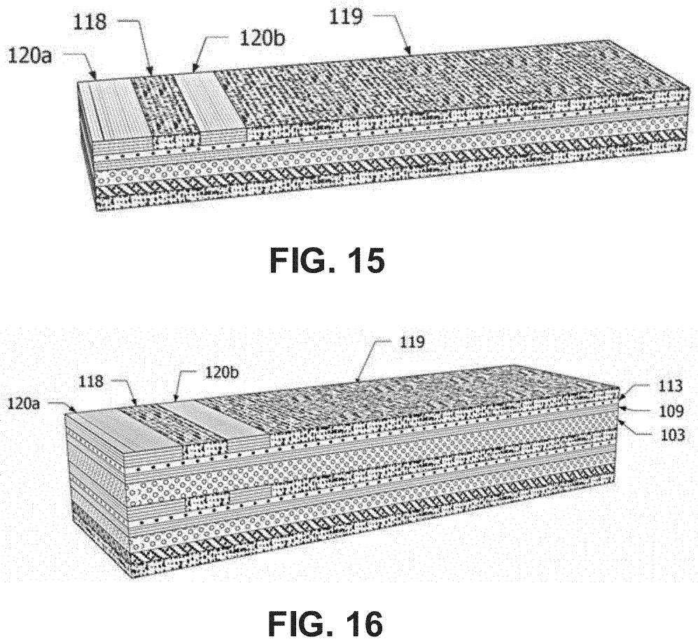

FIG. 15 illustrates the word-line conductor 118, ground plane conductor 119, and matching filler 120a and 120b after the masks 115 and 116 have been removed. This layer comprised of the word-line conductor 118, ground plane conductor 119, and matching filler 120a and 120b is the top of the deck. The device illustrated in FIG. 15 may represent a single layer DRAM cell within a deck, centered around the semiconductor. This top layer may also serve, shared, as the bottom conductor of the next memory cell layer, which may be formed above the memory cell layer of FIG. 15.

FIG. 16 illustrates the results of running the previous steps, described with reference to FIGS. 3-15, to create another deck of memory, resulting in a device that has two layers and can store 2 bits. As similarly described above, the first step will be the addition of the thicker, low-k insulator 103. The thickness and low-k of insulator 103 ensure that the word line 108 of the deck below does not create unwanted disturbance of the access channel in the deck above. Also, if the process is accumulating errors in planarity, the low-k insulator 103 may be given extra thickness and then a planarization step used to restore flatness before further elements of the memory cell are added.

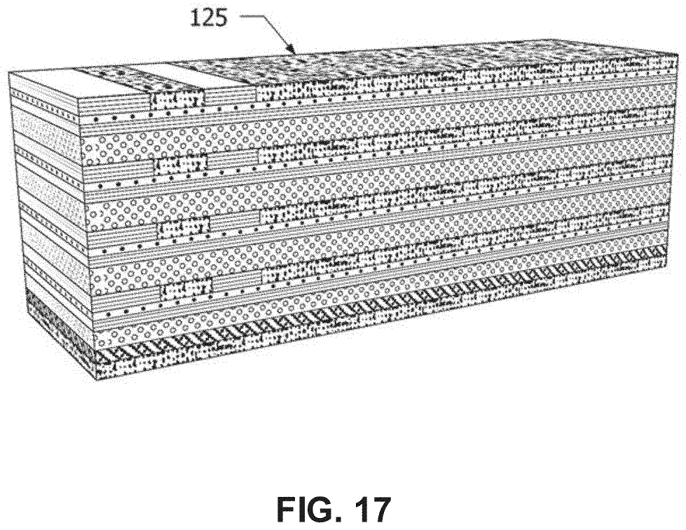

FIG. 17 shows the results of repeating these steps again to create additional decks 125. This process may be repeated for a large number of decks until some practical limit of thickness or desired capacity goal has been reached.

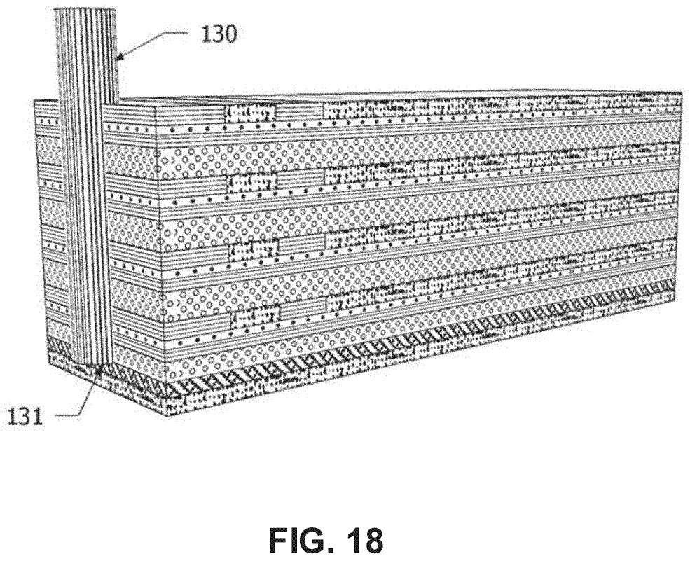

FIG. 18 illustrates the stack of decks described above in reference to FIG. 17, after a vertical data-line via 130 has been added. This has been done by etching a vertical cavity through multiple decks, down to the etch-stop 131, and then filling it with metal, a formation known as a “via”. This step may be repeated for every few decks since there is a limit to the depth of a via which is set by the aspect ratio and directional accuracy of the etching. In some aspects, an etching and via-fill step may be added every 3 or 4 decks or memory cell layers for a typical via etching aspect ratio of 10:1, but future improvements may allow each step to be taller. After the first step, the later via constructions contact onto the top of the previous via, adding up to a columnar via rising through all the decks of a given memory device

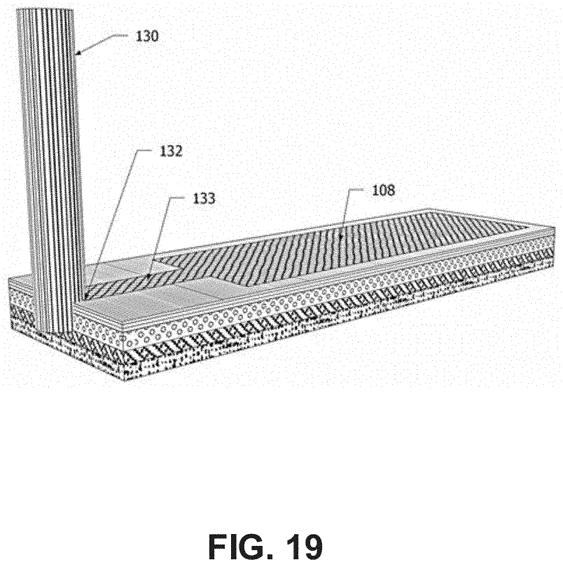

FIG. 19 illustrates in a cut-away view of the memory device described above in reference to FIG. 18, illustrating detail as to how the via for the data-line 130 contacts the end of the silicon bridge 132 section of each semiconductor layer 108, connecting via the access channel 133 of the bridge to the broad capacitor core 108.

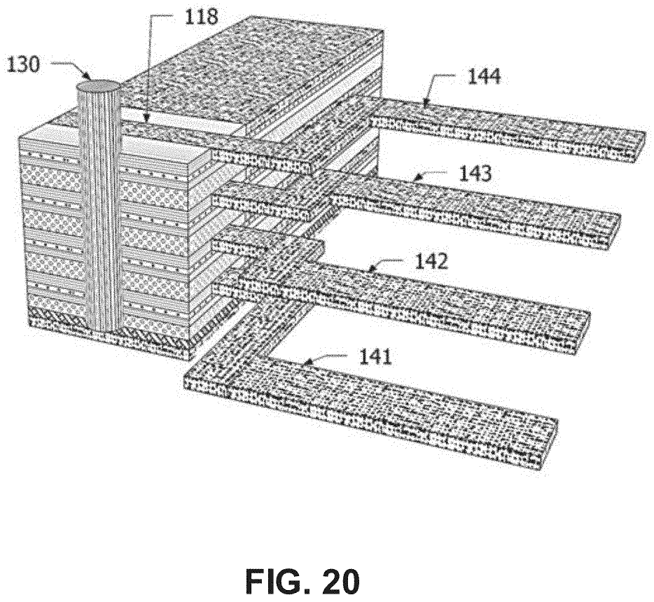

FIG. 20 illustrates that the ends of the word-lines 118 need to have contacts which will reach a vertical via. Each deck has its word-line routed to a different contact landing-line 141, 142, 143, 144, so that a stair-step etch pattern may allow a vertical via to reach each separately from the other word-lines. The stair-step method for word-line contacts has been used in 3D-NAND and can be appropriately adapted to provide functionality for the described DRAM memory device. Thus each landing pad (141, 142, 143, 144) can be individually located to contact its own unique word line.

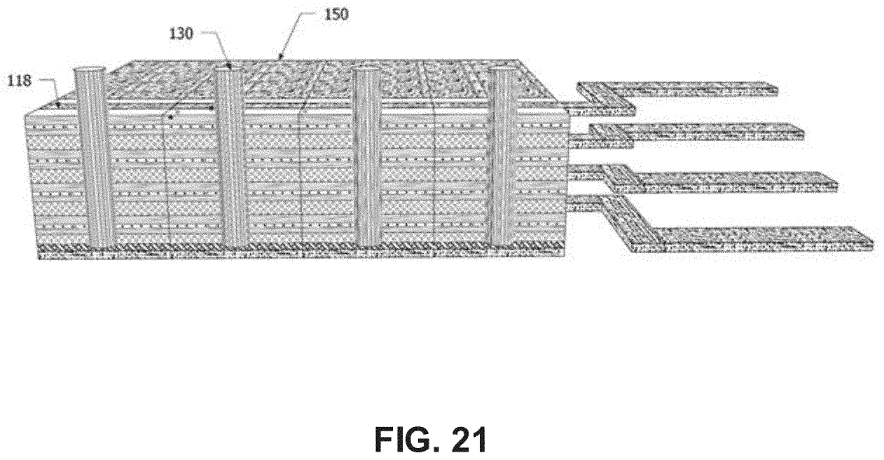

FIG. 21 illustrates a memory device in which more cells 150 may be laid out or arranged beside the stack of memory cells described above in reference to any of FIG. 17, 18, or 20, extending word-lines 118 to create a set of cells which are enabled by the same word-line. Memory stack may extend in adjacent formation over a broad area of a chip.

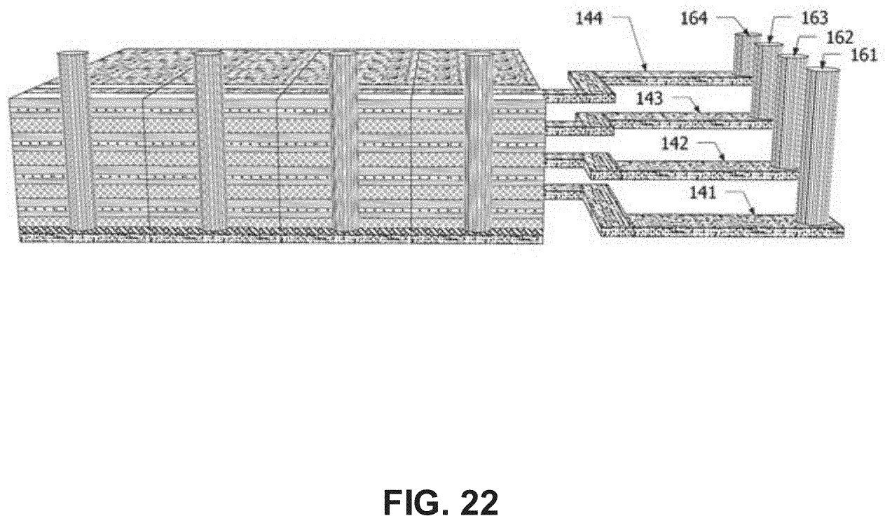

FIG. 22 illustrates an example of how vertical vias 161, 162, 163, 164, which are part of the stair-step formation, may be etched down to contact the individual word-lines at their landing-lines 141, 142, 143, 144.

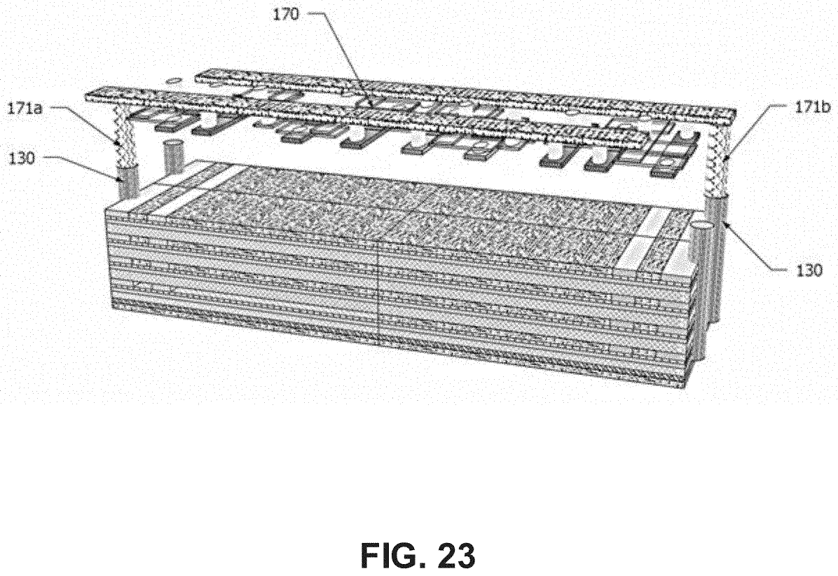

FIG. 23 illustrates how sense amplifiers 170 may be added at the top and data-line contacts 171a, 171b that extend down from the CMOS layer to the underlying data-line vias 130. The sense amplifier modelled here is a standard open data-line design with a data-line at the left and another at the right. These bits are on different word lines and only one of them is active for one operation, the other serves as the reference signal as will be understood by those skilled in DRAM design. The illustration is based upon the channel and metal layout that might be used in an FD-SOI (fully depleted channel SOI) design, but it is also possible to implement a similar layout with a FinFET (fin field effect transistor) or other CMOS process.

The sense amplifiers 170 interleave to fill the area above the cell stack and provide connection to every data-line via. The layout is narrow so that it will fit in the same space as a pair of adjacent planar cells from the stack, so the sense amplifiers 170 take up the same area as the underlying cells. Other arrangements are possible, and there are some edge cases which may need dummy data-lines, to serve as references for a first or last bit in a word. In practice, the design and layout of the sense amplifiers may set limits to the length and width of cells. In some cases, it may be beneficial to add data-line isolation transistors to the sense amplifier 170 so that one sense amp may serve a larger memory cell count, which allows the cells to remain small relative to whatever size of sense amplifier is used. It should be appreciated that in various implementations, various numbers of memory ells may be stacked vertically, and the stacks then arranged adjacent to one another in various patterns or arrangements to form a larger memory device of varying sizes and shapes. A grid-like arrangement is illustrated, however other arrangements and patterns are contemplated herein.

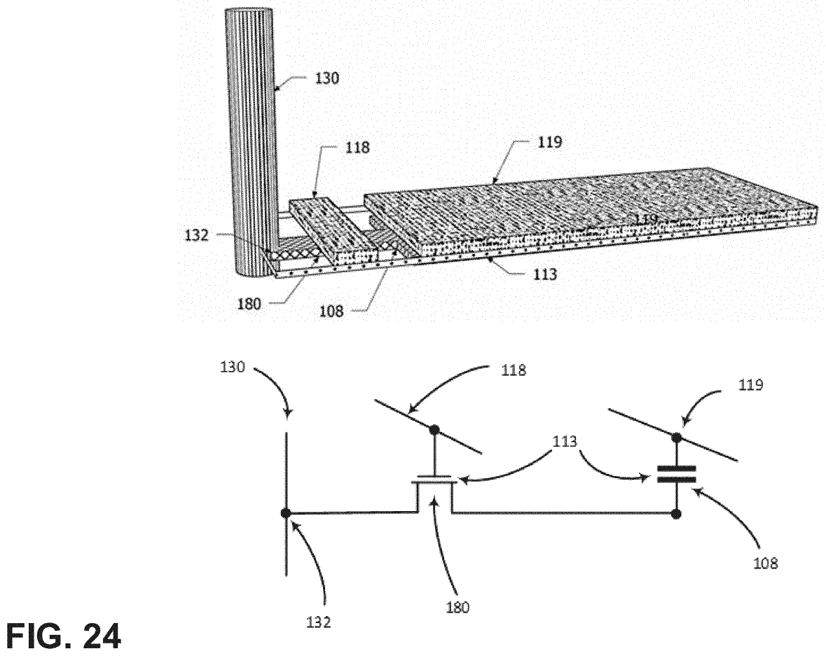

FIG. 24 illustrates the correspondence between the core elements of a single bit cell, as described above, and the logical circuit diagram equivalent. The data-line 130 forms a contact 132 with the conductive bridge. The middle of the semiconductor bridge is the access channel 180 underneath a gate where the word line 118 passes over the dielectric 113. On the other side of the access channel 180, the bridge connects to the broad semiconductor core 108 which is one electrode of the storage capacitor. The dielectric 113 is the interior of the capacitor. The other electrode of the storage capacitor is the ground plane conductor 119. These channels may be understood to extend far to the left and right of the devices illustrated, so that the repeating patterns may form hundreds or thousands of devices.

FIGS. 25-36 illustrate an example process for formation of a second implementation of a DRAM memory device. Specifically, FIG. 25 illustrates an alternative construction of a memory cell, where the shapes of various components are made more linear to allow for use of multi-patterning techniques such as Litho-Etch-Litho-Etch (LELE), Self-Aligned Double Patterning (SADP), or Self-Aligned Quadruple Patterning (SAQP), which can form smaller elements but are best if restricted to linear elements. The finer geometry will also result in less need for filler-steps, as levelling will tend to occur due to pattern fill of the smaller gaps. The memory device illustrated in FIG. 25 similarly is a laminar cell construction with vertical data-lines. In a first step of forming or building the memory device, linear semiconductor channels 201 are formed, such as with SADP or equivalent technique. Masks 202a, 202b are added which cover the area which will be the bridge of the finished cells. The exposed channels may be doped, alloyed, or implanted to increase their conductivity.

FIG. 26 illustrates the capacitor region of the devices, exposed between the masks 202a, 202b, covered with a thin layer of high-k or ferroelectric dielectric material 205. The dielectric deposit 205 may surround the semiconductor channels 201 and may without harm cover the gap between the channels, because the distance between channels is much larger than the thickness of the dielectric. Alternatively, the dielectric may 205 be a chemical modification of the semiconductor, such as an oxide or nitride, which grows only on the semiconductor. The dielectric, in some cases, is on the order of 1 to 3 nm, whereas the distance between channels may be 10 nm or more.

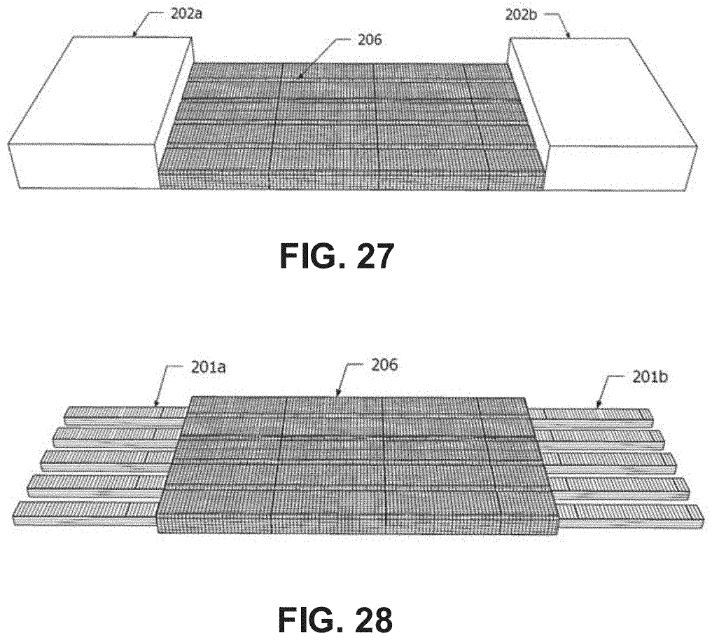

FIG. 27 illustrates that a layer of conductor 206 is deposited on top of the dielectric, in the area exposed between the masks 202a, 202b, forming the ground plane of the cells' capacitors. In some cases, this conductor 206 may fill in between the channels and leaves a top surface close enough to flat to support further construction without needing filler.

FIG. 28 illustrates the devices with the masks 202a, 202b removed. It can be seen that the bridge regions 201a, 201b of the channels are exposed outside the capacitor regions under conductive ground plane 206.

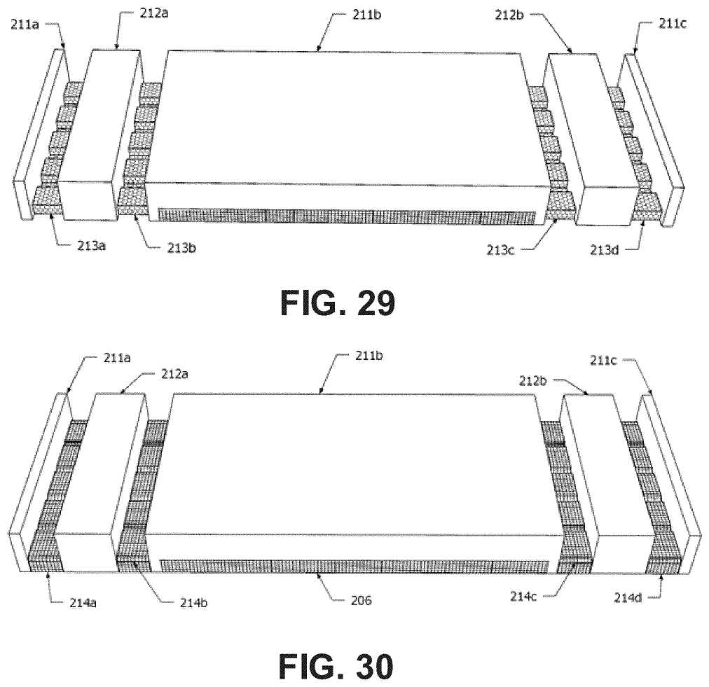

FIG. 29 illustrates adding a new set of masks covering the capacitor region 211b and the access channel regions 212a, 212b of the bridges on the channels. Masks 212a, 212c are the edges of capacitor masks for devices to the left and right. The exposed channels may be doped, alloyed, or implanted to improve conductivity. An insulating layer 213a, 213b, 213c, 213d is grown upon the exposed channel sections, or deposited to cover the exposed sections of the channels. This will form the gate dielectric where the word-line passes around the semiconductor channel.

FIG. 30 illustrates the addition of the word line gate conductors 214a, 214b, 214c, 214d over the gate dielectric between masks 211a, 212a, 211b, 212b, 211c. These conductors 214a, 214b, 214c, 214d fills the valleys between the channels to result in a substantially level surface. The conductor used for the word line may or may not be the same conductor material as used for the capacitor ground plane 206.

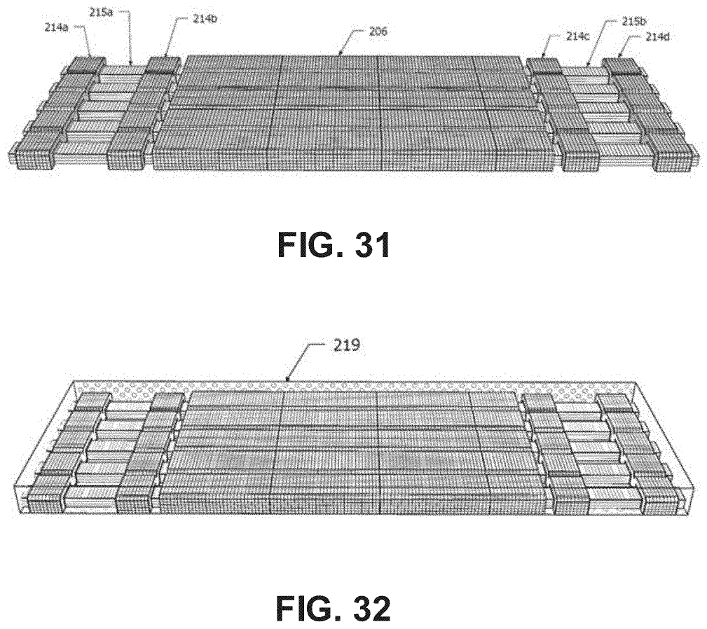

FIG. 31 illustrates the devices with masks 211a, 212a, 211b, 212b, 211c removed. The bridge regions 215a, 215b are illustrated between the access channel gates and word lines 214a, 214b, 214c, 214d and the broad center region forms capacitors under the ground plane 206.

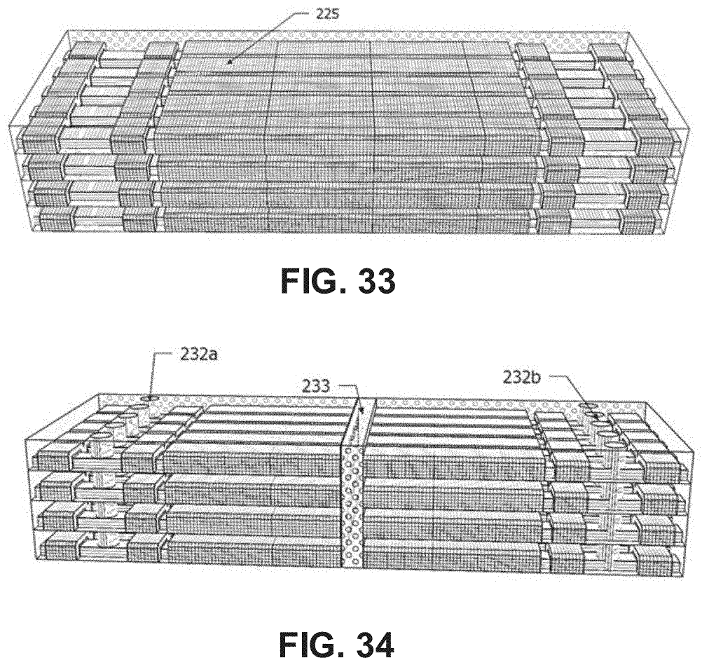

FIG. 32 illustrates the addition of a surrounding filler 219, which may be uniform across all devices, to finish the deck and provide a level surface for the next deck of cells. FIG. 33 illustrates how the previous steps described in reference to FIGS. 25-31 may be repeated to add successive decks (225) of cells on top of the cell described above in reference to FIG. 32.

FIG. 34 illustrates how a set of decks may be processed to etch and fill data-line vias 232a, 232b through the middle of the bridges which are the data-lines connecting to the cells, and to etch a separating void with and fill with low-k insulator 233, which isolates the left and right halves of the capacitor regions to create two distinct memory cells.

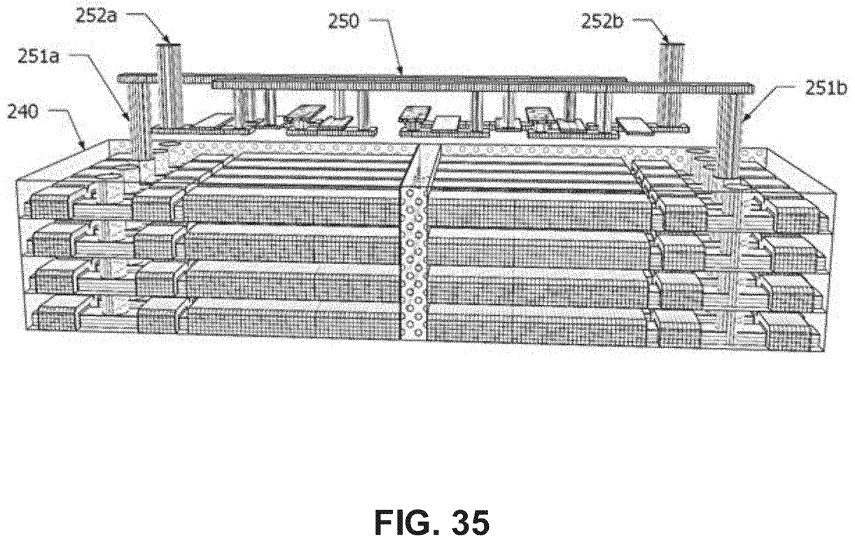

FIG. 35 illustrates how one or more sense amplifiers 250 may be constructed in a CMOS layer above the cell decks 240. The sense amplifier 250 connects with vias 251a, 251b to two data-lines from the cell decks. Each data line is enabled by different word-lines and only one word line is active at any one time, so the sense amplifier 250 has one via reading an active data-line while the other via is using an inactive data-line as a reference. When the sense amplifier settles into a stable state its output value is available at the differential pair 252a, 252b, as is generally known in the art. In other implementations, where the construction order includes a CMOS layer underneath the cell decks, a similar sense amplifier 250 could connect to the data-lines with upward vias. In yet other examples, sense amplifier 250 may be connected through alternately enabled access transistors to more than one pair of data-lines, which enables more silicon to be used for the sense amplifiers if the data cells need to be less than half the size of the sense amplifier 250.

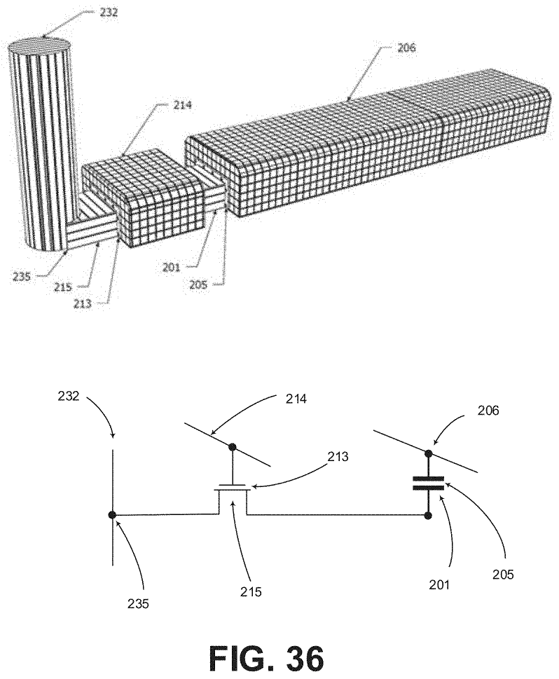

FIG. 36 illustrates the circuit elements of one cell. A comparison to FIG. 24 shows that the logical circuit is the same as for the prior construction method. There is a capacitor to store the data value as a charge on dielectric 205 between semiconductor 201 and ground plane 206. The access channel is on the bridge 215 where word-line 214 and dielectric 213 form a gate on the semiconductor. The data-line 232 contacts 235 the bridge 215. The different fabrication options result in a different shape, but there is a clear one-to-one correspondence in the elements of FIG. 24 and FIG. 36, showing that these represent alternative proportions for elements of a memory device that operates in a similar fashion.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the invention to the specific form or forms disclosed but, on the contrary, the intention is to cover all modifications, alternative constructions, and equivalents falling within the spirit and scope of the invention, as defined in the appended claims.

The use of the terms “a” and “an” and “the” and similar referents in the context of describing the disclosed embodiments (especially in the context of the following claims) are to be construed to cover both the singular and the plural, unless otherwise indicated herein or clearly contradicted by context. Similarly, use of the term “or” is to be construed to mean “and/or” unless contradicted explicitly or by context. The terms “comprising,” “having,” “including,” and “containing” are to be construed as open-ended terms (i.e., meaning “including, but not limited to,”) unless otherwise noted. The term “connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within the range, unless otherwise indicated herein, and each separate value is incorporated into the specification as if it were individually recited herein. The use of the term “set” (e.g., “a set of items”) or “subset” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but the subset and the corresponding set may be equal. The use of the phrase “based on,” unless otherwise explicitly stated or clear from context, means “based at least in part on” and is not limited to “based solely on.”

Conjunctive language, such as phrases of the form “at least one of A, B, and C,” or “at least one of A, B and C,” (i.e., the same phrase with or without the Oxford comma) unless specifically stated otherwise or otherwise clearly contradicted by context, is otherwise understood within the context as used in general to present that an item, term, etc., may be either A or B or C, any nonempty subset of the set of A and B and C, or any set not contradicted by context or otherwise excluded that contains at least one A, at least one B, or at least one C. For instance, in the illustrative example of a set having three members, the conjunctive phrases “at least one of A, B, and C” and “at least one of A, B and C” refer to any of the following sets: {A}, {B}, {C}, {A, B}, {A, C}, {B, C}, {A, B, C}, and, if not contradicted explicitly or by context, any set having {A}, {B}, and/or {C} as a subset (e.g., sets with multiple “A”). Thus, such conjunctive language is not generally intended to imply that certain embodiments require at least one of A, at least one of B and at least one of C each to be present. Similarly, phrases such as “at least one of A, B, or C” and “at least one of A, B or C” refer to the same as “at least one of A, B, and C” and “at least one of A, B and C” refer to any of the following sets: {A}, {B}, {C}, {A, B}, {A, C}, {B, C}, {A, B, C}, unless differing meaning is explicitly stated or clear from context. In addition, unless otherwise noted or contradicted by context, the term “plurality” indicates a state of being plural (e.g., “a plurality of items” indicates multiple items). The number of items in a plurality is at least two but can be more when so indicated either explicitly or by context.

Operations of processes described herein for manufacturing DRAM memory cells of devices can be performed in any suitable order unless otherwise indicated herein or otherwise clearly contradicted by context. In an embodiment, a process such as those processes described herein (or variations and/or combinations thereof) for manufacturing one or more DRAM memory devices is performed under the control of one or more computer systems configured with executable instructions and is implemented as code (e.g., executable instructions, one or more computer programs or one or more applications) executing collectively on one or more processors, by hardware or combinations thereof. In an embodiment, the code is stored on a computer-readable storage medium, for example, in the form of a computer program comprising a plurality of instructions executable by one or more processors. In an embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In an embodiment, code (e.g., executable code or source code) is stored on a set of one or more non-transitory computer-readable storage media having stored thereon executable instructions that, when executed (i.e., as a result of being executed) by one or more processors of a computer system, cause the computer system to perform operations described herein. The set of non-transitory computer-readable storage media, in an embodiment, comprises multiple non-transitory computer-readable storage media, and one or more of individual non-transitory storage media of the multiple non-transitory computer-readable storage media lack all of the code while the multiple non-transitory computer-readable storage media collectively store all of the code. In an embodiment, the executable instructions are executed such that different instructions are executed by different processors—for example, in an embodiment, a non-transitory computer readable storage medium stores instructions and a main CPU executes some of the instructions while a graphics processor unit executes other instructions. In another embodiment, different components of a computer system have separate processors and different processors execute different subsets of the instructions.

Accordingly, in an embodiment, computer systems are configured to implement one or more services that singly or collectively perform operations of processes described herein, and such computer systems are configured with applicable hardware and/or software that enable the performance of the operations. Further, a computer system, in an embodiment of the present disclosure, is a single device and, in another embodiment, is a distributed computer system comprising multiple devices that operate differently such that the distributed computer system performs the operations described herein and such that a single device does not perform all operations.

The use of any and all examples or exemplary language (e.g., “such as”) provided herein is intended merely to better illuminate embodiments of the invention and does not pose a limitation on the scope of the invention unless otherwise claimed. No language in the specification should be construed as indicating any non-claimed element as essential to the practice of the invention.

Embodiments of this disclosure are described herein, including the best mode known to the inventors for building the described DRAM memory cell. Variations of those embodiments may become apparent to those of ordinary skill in the art upon reading the foregoing description. The inventors expect skilled artisans to employ such variations as appropriate, and the inventors intend for embodiments of the present disclosure to be practiced otherwise than as specifically described herein. Accordingly, the scope of the present disclosure includes all modifications and equivalents of the subject matter recited in the claims appended hereto as permitted by applicable law. Moreover, any combination of the above-described elements in all possible variations thereof is encompassed by the scope of the present disclosure unless otherwise indicated herein or otherwise clearly contradicted by context.

All references including publications, patent applications, and patents cited herein are hereby incorporated by reference to the same extent as if each reference were individually and specifically indicated to be incorporated by reference and were set forth in its entirety herein.

In some aspects, the described system and techniques may include one or more of the following features. It should be appreciated that various combinations of these features are completed herein, and that language indicating inclusion of a combination of features is not a requirement that those features operation in combination to provide one or more advantages as described herein.

1. In one aspect, a deck of one-transistor, one-capacitor (1T1C) memory cells are constructed with elements formed from alternating layers of conductor, dielectric insulation, and semiconductor, so that the devices shall be substantially planar and thin, where some of the layers are uniformly deposited and some other layers contain flat shaped elements, where data storage capacitance for the cells shall be formed with one electrode belonging to the device separated by an insulator layer from the other electrode formed of a ground plane which is a substantially horizontal layer within the deck, where the word lines which activate the access gates of each memory cell are incorporated within the planes of the deck, where multiple decks are stacked in alignment above each other, where the data-lines which move the charges to and from the cells are etched and conductor-filled to run vertically through the decks making contacts to the access channels in each deck, where the data-lines terminate with connection either above or below the memory cells which will connect to sense amplifiers, where multiple decks are constructed vertically to obtain multiple layers of memory.

2. The elements of (1) where a filler is added by self-aligned complementary use of the same masks which shaped the device elements, such that the filler shall substantially match the thickness of those other elements, resulting in a substantially level top across both the device elements and the filler.

3. The elements of (1) where the insulating materials used for capacitor or gate dielectrics may be deposited as uniform planar layers between the layers of conductors or semiconductors made substantially planar by use of fillers, such that the insulating layers are of uniform thickness and substantially free of discontinuities such as step changes in the surface level.

4. The elements of (1) where an insulating layer of dielectric may be doped or alloyed in the capacitor areas to optimize for properties including ferroelectric or antiferroelectric behavior.

5. The elements of (1) where multiple decks are accurately aligned to ensure that elements with the same function in each deck are directly above each other and may directly interconnect by vertical vias of width comparable to the smallest elements of the cells.

6. The elements of (5), where at intervals in the process vias are etched through the layers below and filled with suitable conductors completing a vertical circuit which contacts and connects the functionally related elements in multiple layers to form a vertical circuit.

7. The elements of (1) where CMOS sense amps and control elements are added after the memory stack is completed such that prior to CMOS elements being added the memory stack may undergo one or more annealing or other high temperature formation processes which would not be compatible with presence of the CMOS elements.

8. The elements of (1), where when sufficient decks are accumulated that the surface planarity needs to be improved, the process uses a thicker version of one layer which can be planarized to return to an ideal flat surface while preserving the functional sequence of layers in the deck.

9. The elements of (1) where each deck contains substantially the same pattern for the word-line but where the word-line in each deck may be extended to a unique location of contact pad where vias may reach it separately from other word lines above and below, where that unique detail is drawn by use of mask less lithography such as electron beam lithography.

10. The elements of (1), where the semiconductors are formed from silicon which is deposited as a thin film and may be annealed or otherwise treated to refine its properties as an access channel and capacitor electrode.

11. The elements of (1) where the semiconductors are oxides such as titanium dioxide, or tungsten trioxide, or IWO (indium oxide with tungsten doping) or IGZO (indium gallium zinc oxide), which have known properties making them suitable for memory cell access gates.

12. In another aspect, a deck of 1T1C memory cells is constructed such that the deck is substantially planar to allow another deck to be constructed on top, where each deck can be formed of materials deposited and not requiring use of materials which are part of the substrate, where multiples of the cells within each deck are controlled by shared word-lines which isolate the use of any one data-line to just one memory cell in an enabled word, and where the bit cells are connected through access channels to contact vertically etched vias which transfer data values in the form of charge into or out of capacitors formed of a horizontal electrode connected to the access channel and a thin dielectric layer separating a second horizontal ground plane electrode, where multiple decks are constructed vertically to obtain multiple layers of memory.

13. The elements of (12) where multiple decks are constructed aligned exactly above each other such that vertical data-line vias passing through multiple decks shall correctly connect the matching horizontal cell access transistors which controls the flow of charge in or out of the cell's storage capacitor.

14. The elements of (12), where the sense amplifiers and active controls may be formed in a CMOS layer bonded or deposited above the multiple decks of the memory stack and connected to the matching data-line which contacts a vertical set of memory cells.

15. The elements of (14), where high temperature formation and annealing processes may be used prior to the addition of the sense amplifiers and control circuits so that the additive construction of thin films for conductors, semiconductors, and dielectrics may be optimized without the limitations which the presence of analog and switching circuits may require.

16. The elements of (12) where the substrate underlying the memory deck may be of a material such as graphite or ordinary purity silicon or glass, possibly layered or alloyed, materials optimized for low cost, mechanical properties, thermal conductivity, and compatibility with the expansion coefficients of materials used in the memory decks.

17. The elements of (14), where additional analog or switching functions for computation or processing may be included within the CMOS layer beside the sense amplifiers and control circuits or bonded or deposited in one or more additional CMOS layers above.

18. The elements of (12), where the sense amplifiers and active controls may be formed in a CMOS layer below the multiple decks of the memory stack and connected to the matching data-line via which contacts a vertical set of memory cells.

19. The elements of (18), where additional analog or switching functions for computation or processing may be included within the CMOS layer beside the sense amplifiers and control circuits or bonded or deposited in one or more additional CMOS layers above.

What is claimed is:

1. A memory device comprising:
a plurality of dynamic random access memory cells forming a stacked structure, individual dynamic random access memory cells of the plurality of dynamic random access memory cells comprising:
a capacitive element formed of two substantially planar electrodes separated by an insulating layer, the capacitive element being substantially planar;
a transistor in communication with the capacitive element, the transistor being substantially planar with the capacitive element; and
a word line that activates the access gate of the transistor when a voltage is applied to the access gate, the word line at least in part formed proximate to and substantially parallel with the capacitive element; and
at least one data line oriented in a vertical direction relative to the stacked structure, the at least one data line in communication with capacitive elements through the access gate of individual dynamic random access memory cells of the plurality of dynamic random access memory cells and operable to store and access charge stored in individual capacitive elements of the plurality of dynamic random access memory cells representing data stored by the individual capacitive elements.

2. The memory device of claim 1, further comprising:
at least one sense amplifier formed in a complementary metal-oxide-semiconductor (CMOS) layer and in communication with the at least one data line.

3. The memory device of claim 2, wherein the CMOS layer is located proximate to a top most capacitive element of the stacked structure.

4. The memory device of claim 2, wherein at least one of the capacitive element, the transistor, the word line, or the at least one data line is formed using a high temperature prior to the CMOS layer being added to the stacked structure.

5. The memory device of claim 1, wherein a first electrode of the two substantially planar electrodes and an access gate of the transistor are formed by a common semiconductor layer.

6. The memory device of claim 5, wherein the semiconductor layer is formed via silicon deposition.

7. The memory device of claim 5, wherein the semiconductor layer is treated via an annealing process.

8. The memory device of claim 1, wherein at least one of the pluralities of dynamic random access memory cells further comprises a filler layer proximate to and at least partially overlapping the capacitive element, wherein the filler layer has a substantially level surface opposite the capacitive element.

9. The memory device of claim 1, wherein the insulating layer is formed by material deposition to have a uniform thickness substantially free of discontinuities.

10. The memory device of claim 1, wherein the insulating layer comprises ferroelectric or antiferroelectric properties.

11. The memory device of claim 1, wherein the plurality of dynamic random access memory cells are aligned to form the stacked structure such that the at least one data line formed in a via contacts the transistors via access channels of each of the plurality of dynamic random access memory cells.

12. The memory device of claim 11, wherein the individual word lines of the individual dynamic random access memory cells of the plurality of dynamic random access memory cells comprise a substantially common pattern terminating in a uniquely located contact pad to allow individual activation of the individual word lines.

13. A memory device comprising:
a plurality of substantially planar memory cells arranged in a stack, individual memory cells of the plurality of memory cells comprising:
a capacitive element formed of two electrodes separated by an insulating layer;
a transistive element in communication with the capacitive element; and
a word line that activates the access gate of the transistive element when charged; and
at least one data line oriented perpendicular relative to the stack, the at least one data line in communication with capacitive elements of individual memory cells of the plurality of memory cells and operable to store and read charge from individual capacitive elements of individual memory cells of the plurality of memory cells representing data stored by the individual capacitive elements.

14. The memory device of claim 13, wherein the at least one data line is vertically etched to form at least one via that spans multiple memory cells of the plurality of memory cells and is in communication with an access channel of the transitive element of each of the multiple memory cells.

15. The memory device of claim 13, wherein the memory device comprises a plurality of stacks positioned adjacent to at least one other of the plurality of stacks, and wherein individual word lines span multiple stacks of the plurality of stacks.

16. The memory device of claim 13, wherein individual memory cells are formed via deposition of material in at least one layer of conductor material, at least one layer of dielectric insulation material, and at least one layer of semiconductor material.

17. The memory device of claim 16, wherein the at least one layer of semiconductor material forms the access channel of the transitive element.

18. The memory device of claim 13, wherein the plurality of planar memory cells are aligned vertically on top of one another.

19. The memory device of claim 13, further comprising at least one sense amplifier and at least one control circuit formed in a complementary metal-oxide-semiconductor (CMOS) layer deposited above the plurality of substantially planar memory cells arranged in the stack and in communication with the at least one data line.

20. The memory device of claim 13, wherein individual memory cells comprise a substrate comprising at least one of graphite, silicon, or glass.

21. The memory device of claim 13, further comprising at least one sense amplifier and at least one control circuit formed in a complementary metal-oxide-semiconductor (CMOS) layer positioned below the plurality of substantially planar memory cells arranged in the stack and in communication with the at least one data line.

22. The memory device of claim 13, further comprising:
a second plurality of substantially planar memory cells arranged in a second stack, the second stack proximate to the first stack and forming a mirrored orientation with respect to the first stack.

23. The memory device of claim 22, wherein the stack and the second stack are formed by cutting a deep trench through a single stack comprising the plurality of substantially planar memory cells, wherein the plurality of substantially planar memory cells are arranged two substantially planar memory cells to a layer of the single stack.
